(19) United States
(12) Patent Application Publication
(10) Pub. No.: US 2026/0125825 A1
(43) Pub. Date: May 7, 2026

(54) GALLIUM NITRIDE SINGLE CRYSTAL SUBSTRATE AND METHOD OF PRODUCING SAME

(71) Applicant: SUMITOMO CHEMICAL COMPANY, LIMITED, Tokyo (JP)

(72) Inventors: Takayuki SUZUKI, Ibaraki (JP); Takashi SATO, Ibaraki (JP); Toshio KITAMURA, Ibaraki (JP); Tetsuji FUJIMOTO, Ibaraki (JP)

(21) Appl. No.: 19/365,286

(22) Filed: Oct. 22, 2025

(30) Foreign Application Priority Data
Nov. 1, 2024 (JP) 2024-193239

(51) Int. Cl. C30B 29/40; C01B 21/06; C30B 25/20

(52) U.S. Cl. CPC C30B 29/406; C01B 21/0632; C30B 25/20; C01P 2006/32

(57) ABSTRACT

A gallium nitride single crystal substrate in which a low-index crystal plane closest to a principal surface of the substrate is a (0001) plane, wherein resistivity of the substrate at 200° C. is 1×10⁻² Ω·cm or lower, and thermal conductivity of the substrate along a thickness direction at 200° C. is 80 W/mk or higher.

### FIELD AND BACKGROUND OF THE INVENTION

The present disclosure relates to a gallium nitride single crystal substrate and a method of producing same.

Group III nitride semiconductors, typically represented by gallium nitride (GaN), are widely used as materials for semiconductor devices such as light-emitting devices and electronic devices. In order to improve the quality (e.g., semiconductor characteristics) of semiconductor devices constituted from group III nitride semiconductors, it has been desired to produce semiconductor stacks for manufacturing semiconductor devices or free-standing nitride semiconductor substrates so as to have satisfactory crystal quality.

In a GaN single crystal substrate, an impurity is doped so that resistivity is reduced.

In particular, for applications in high-power laser diodes and power devices, further reduction of resistivity of a GaN single crystal substrate is needed. From the viewpoint of reducing resistivity, it is necessary to increase the concentration of impurities. As one such impurity, germanium (Ge) has been studied because even at high concentrations it hardly degrades crystallinity of GaN (see, for example, Patent Document 1).

### RELATED APPLICATION

Patent Document 1: Japanese Patent Application Publication No. 2021-195280

### SUMMARY OF THE INVENTION

A GaN single crystal substrate may in some cases be mounted on a heat sink when fabricated into a semiconductor device. From the viewpoint of enhancing heat transfer to the heat sink, a GaN single crystal substrate used for semiconductor devices is expected to have high thermal conductivity. However, thermal conductivity of a GaN single crystal substrate tends to decrease by addition of germanium.

On the other hand, in an environment in which a semiconductor device is actually used, temperature may rise due to operation of the device. In this regard, thermal conductivity has conventionally been measured under room-temperature conditions, and no attention has been paid to measurement under high-temperature conditions. The present inventors examined variation of thermal conductivity of gallium nitride due to temperature, and it was confirmed that even when thermal conductivity is high under room-temperature conditions, it decreases due to rising temperature.

Thus, with a GaN single crystal substrate, when germanium is added in a high concentration in order to reduce resistivity, even if high thermal conductivity can be achieved under room-temperature conditions, it may not be possible to maintain high thermal conductivity under high-temperature conditions.

It is an objective of the present disclosure to provide a technique capable of maintaining high thermal conductivity under a high-temperature environment while reducing resistivity in a gallium nitride single crystal substrate.

According to one aspect of the present disclosure, there is provided a gallium nitride single crystal substrate in which a low-index crystal plane closest to a principal surface of the substrate is a (0001) plane, wherein
resistivity of the substrate at 200° C. is 1×10⁻² Ω·cm or lower,
and thermal conductivity of the substrate along a thickness direction at 200° C. is 80 W/mk or higher.

According to another aspect of the present disclosure, there is provided a method of producing a gallium nitride single crystal substrate, the method including:
(a) preparing a base substrate constituted from a gallium nitride single crystal in which a low-index crystal plane closest to a principal surface of the base substrate is a (0001) plane; and
(b) epitaxially growing a gallium nitride single crystal on the principal surface of the base substrate,
wherein in (b), under an ammonia-containing atmosphere with a growth pressure greater than 1 atm and 1.5 atm or lower, a source gas for forming the gallium nitride single crystal is supplied onto the base substrate, and concurrently ammonia is supplied from around a support member supporting the base substrate.

According to the present disclosure, it is possible to maintain high thermal conductivity even under a high-temperature environment while reducing resistivity in a gallium nitride single crystal substrate.

### BRIEF DESCRIPTION OF THE DRAWINGS

FIG. 1A illustrates a schematic cross-sectional view illustrating a part of a method of producing a gallium nitride single crystal substrate according to an embodiment of the present disclosure;

FIG. 1B illustrates a schematic cross-sectional view illustrating a part of the method of producing a gallium nitride single crystal substrate according to an embodiment of the present disclosure;

FIG. 1C illustrates a schematic cross-sectional view illustrating a part of the method of producing a gallium nitride single crystal substrate according to an embodiment of the present disclosure;

FIG. 2 illustrates a flowchart illustrating the method of producing a gallium nitride single crystal substrate according to an embodiment;

FIG. 3 is a schematic configuration diagram illustrating an example of an HVPE apparatus;

FIG. 4 illustrates thermal conductivity R1 along a thickness direction at 25° C. and 200° C. according to examples; and

FIG. 5 illustrates thermal conductivity R2 along an in-plane direction at 25° C. and 200° C. according to examples.

### DETAILED DESCRIPTION

### <Findings Obtained by the Inventors>

Findings obtained by the present inventors will be described first.

The present inventors examined correlation between resistivity and thermal conductivity of GaN crystals heavily doped with germanium. As a result, it was confirmed that in the case of germanium, compared for example with silicon, it is feasible to reduce resistivity of GaN crystals while maintaining high thermal conductivity under room-temperature environment. However, it was also confirmed that even GaN crystals exhibiting high thermal conductivity under room-temperature environment may, under a high-temperature environment, fail to realize desired heat dissipation property when fabricated into a semiconductor device, because thermal conductivity decreases significantly even though resistivity does not increase.

The present inventors further examined a decrease in thermal conductivity due to rising temperature, and found that such a decrease is greatly affected by point defects introduced into GaN crystals. In GaN crystals, lattice mismatch may occur due to addition of impurities. Distortion of the crystal lattice may cause desorption of nitrogen atoms from the lattice, forming nitrogen vacancies. These nitrogen vacancies may form point defects. The greater the number of such point defects, the more likely thermal conductivity tends to decrease due to rising temperature.

For this reason, the present inventors have examined a method for reducing point defects in a GaN crystal, in particular point defects formed by desorption of nitrogen atoms. As a result, from the viewpoint of suppressing desorption of nitrogen atoms, it has been found that in crystal growth of a GaN crystal, it is preferable to set the growth pressure to a pressurizing condition and to supply ammonia as a holder purge gas under an ammonia-containing atmosphere.

The term “holder purge” refers to supplying a predetermined gas around a holder, for example during crystal growth in an HVPE apparatus, for the purpose of removing crystals deposited on the holder for holding a base substrate or preventing a source gas from reaching the back side of the holder. In the holder purge, for example, a gas is supplied and flowed from a side opposite to a holding surface of the holder for the base substrate, that is, from the back side of the holder, toward a peripheral portion of the holder. This makes it feasible to locally bring the surroundings of the holder into a positive pressure state.

As a gas used for the holder purge, from the viewpoint of the above purposes, nitrogen gas, hydrogen gas, etc. is usually used. According to examinations by the present inventors, it has been found that, by supplying ammonia instead of nitrogen gas or the like, desorption of nitrogen atoms in a GaN crystal can be suppressed and point defects can be reduced.

The present disclosure is based on the above findings found by the inventors.

### Detailed Description of Embodiments of the Present Disclosure

Next, an embodiment of the present disclosure will be described below with reference to the drawings. It should be noted that the present disclosure is not limited to these examples, but is defined by the claims, and is intended to include all modifications within the meanings and scope that are equivalent to the claims.

### First Embodiment of the Present Disclosure

Hereinafter, a first embodiment of the present disclosure will be described with reference to the drawings.

### (1) Gallium Nitride Single Crystal Substrate

A gallium nitride single crystal substrate (hereinafter also simply referred to as a GaN substrate) according to this embodiment is configured as a disk-shaped substrate used in manufacturing a semiconductor stack or a semiconductor device. The GaN substrate is a free-standing substrate constituted from a gallium nitride (GaN) single crystal.

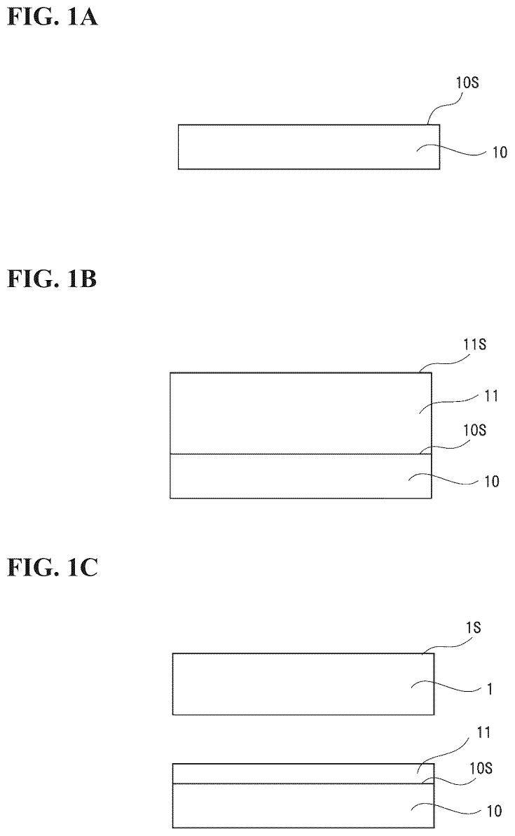

As illustrated in FIG. 1C, the GaN substrate 1 has a principal surface is serving as an epitaxial growth surface. The principal surface is of the GaN substrate 1 is a so-called epi-ready surface. A low-index crystal plane closest to the principal surface is of the GaN substrate 1 is, for example, a (0001) plane (+c-plane, Ga-polarity plane). Hereinafter, the (0001) plane is also referred to as the c-plane. The principal surface is of the GaN substrate 1 is, for example, mirror-finished, and the root mean square roughness (RMS) of the principal surface is of the GaN substrate 1 is preferably less than 1 nm.

Further, although the diameter of the GaN substrate 1 is not particularly limited, it is, for example, 50 mm or more. If the diameter of the GaN substrate 1 is less than 50 mm, productivity of semiconductor devices tends to be reduced. Therefore, it is preferable that the diameter of the GaN substrate 1 be 50 mm or more. The thickness of the GaN substrate 1 is, for example, 300 μm or more and 1 mm or less. If the thickness of the GaN substrate 1 is less than 300 μm, the mechanical strength of the GaN substrate 1 may decrease, making it difficult to maintain a free-standing state. Therefore, it is preferable that the thickness of the GaN substrate 1 be 300 μm or more.

The GaN substrate 1 is constituted such that its resistivity is low even in a high-temperature environment assuming heat generation of a device. Specifically, the resistivity of the GaN substrate 1 at 200° C. is 1×10⁻² Ω·cm or lower, preferably less than 1×10⁻³ Ω·cm. In general, the resistivity tends to decrease due to an increase in temperature, but in the GaN substrate 1 of this embodiment, the resistivity can be made lower. With a semiconductor device fabricated from such a GaN substrate 1, power loss can be suppressed or a high switching speed can be maintained even in a high-temperature environment. The lower limit of resistivity at 200° C. is not particularly limited, but may be, for example, 1.0×10⁻⁴ Ω·cm or higher.

The GaN substrate 1 is also constituted such that its resistivity is low also in a low-temperature environment. Specifically, the resistivity of the GaN substrate 1 at 25° C. is preferably 1.0×10⁻⁴ Ω·cm or higher and 1.0×10⁻² Ω·cm or lower, and more preferably 1.0×10⁻⁴ Ω·cm or higher and less than 1.0×10⁻³ Ω·cm. According to the GaN substrate 1 having such resistivity, the resistivity can be kept low in both low-temperature and high-temperature environments.

From the viewpoint of reducing resistivity, the GaN substrate 1 is preferably constituted so as to contain an impurity including germanium (Ge). The impurity is to at least include Ge, and may further include other n-type impurities such as silicon (Si). With Ge, compared with other n-type impurities, high crystallinity of the GaN crystal can be maintained even when added at a high concentration.

The Ge concentration in the GaN substrate 1 is not particularly limited as long as the resistivity at 200° C. or 25° C. satisfies the above range. The Ge concentration is preferably 1.0×10¹⁸ cm⁻³ or higher, more preferably 5.0×10¹⁸ cm⁻³ or higher, still more preferably 1.8×10¹⁹ cm⁻³ or higher, and even more preferably 1.0×10²⁰ cm⁻³ or higher. On the other hand, the upper limit of the Ge concentration is not particularly limited, but is preferably 1.0×10²¹ cm⁻³ or lower, more preferably 5.0×10²⁰ cm⁻³ or lower. Although a higher Ge concentration can reduce the resistivity more, point defects are likely to occur, and the thermal conductivity tends to decrease in a high-temperature environment. However, in this embodiment, the thermal conductivity can be maintained high by performing crystal growth under conditions that suppress point defects, as will be described later.

In addition to impurities such as Ge, oxygen (O) and/or hydrogen (H) may be unavoidably mixed into the GaN substrate 1. O may lower thermal conductivity in a room (ambient) temperature environment or may worsen a decrease in thermal conductivity due to an increase in temperature. Therefore, the O concentration is preferably sufficiently lower than the Ge concentration so as to be negligible, for example, preferably 1/10 or less of the Ge concentration, more preferably 1/100 or less thereof. Specifically, the O concentration is preferably 6×10¹⁶ cm⁻³ or lower. The H concentration is preferably 1.0×10¹⁷ cm⁻³ or lower.

The GaN substrate 1 of this embodiment is formed under conditions whereby desorption of nitrogen atoms is suppressed as described later; as a result, the GaN substrate 1 is constituted so as to have few point defects and be able to maintain high thermal conductivity even in a high-temperature environment. Specifically, when the thermal conductivity of the GaN substrate 1 along a thickness direction of the principal surface 1s is defined as R1, R1(H) at 200° C. is 80 W/mk or higher and 120 W/mk or lower. Therefore, the GaN substrate 1 can easily release heat in the thickness direction even in a high-temperature environment of 200° C., thereby achieving high heat dissipation.

The GaN substrate 1 is also constituted such that it also has high thermal conductivity in a room temperature environment, not only high-temperature environment. Specifically, R1(L), which is the thermal conductivity in the thickness direction at 25° C., is preferably 120 W/mk or higher. The upper limit is not particularly limited, but may be, for example, 230 W/mk or lower.

The GaN substrate 1 is also constituted such that the thermal conductivity along the in-plane direction is high in addition to the thickness direction. Specifically, when the thermal conductivity of the GaN substrate 1 along the in-plane direction of the principal surface 1s is defined as R2, R2(H) at 200° C. is preferably 80 W/mk or higher and 110 W/mk or lower. The GaN substrate 1 is also constituted such that it also has high thermal conductivity in a room temperature environment, and R2(L), which is the thermal conductivity in the in-plane direction at 25° C., is preferably 150 W/mk or higher. The upper limit is not particularly limited, but may be, for example, 250 W/mk or lower. With such a configuration, heat can be easily diffused in the in-plane direction in the GaN substrate 1.

Since desorption of nitrogen atoms and resulting generation of point defects are suppressed in the GaN substrate 1, reduction of thermal conductivity due to temperature increase is suppressed. That is, the thermal conductivity R1 in the thickness direction of the GaN substrate 1 has a small rate of change when the temperature is raised from low temperature to high temperature. Specifically, it is preferable that the GaN substrate 1 have a small rate of change of thermal conductivity R1 in the thickness direction when the temperature is raised from 25° C. to 200° C., and that the rate of change x be 0.5 or less. Here, the rate of change x of thermal conductivity R1 in the thickness direction with temperature increase is expressed by x=(R1(L)−R1(H))/R1(L) using R1(L) at 25° C. and R1(H) at 200° C., and it is preferable that x satisfy x≤0.5. The lower the x, the smaller the decrease in thermal conductivity due to temperature increase, indicating that high thermal conductivity can be maintained even at high temperatures.

The thermal conductivity R2 in the in-plane direction of the GaN substrate 1 preferably has, similarly to the thermal conductivity R1 in the thickness direction, a small rate of change when the temperature is raised from 25° C. to 200° C., and the rate of change y is preferably 0.6 or less. Here, the rate of change y of the thermal conductivity R2 in the in-plane direction with temperature increase is expressed by y=(R2(L)−R2(H))/R2(L) using R2(L) at 25° C. and R2(H) at 200° C., and it is preferable that y satisfy y≤0.6. The lower the y, the smaller the decrease in thermal conductivity due to temperature increase, indicating that high thermal conductivity can be maintained even at high temperatures.

For the GaN substrate 1, when a semiconductor device is fabricated therefrom, it is preferable to have a high carrier concentration from the viewpoint of improving operating speed and reducing power loss. The carrier concentration is determined depending on the concentration of impurities contained in the GaN crystal, for example, the germanium concentration, and becomes substantially equal to the germanium concentration. Specifically, the carrier concentration is preferably 1.0×10¹⁸ cm⁻³ or higher, more preferably 5.0×10¹⁸ cm^{<3} or higher, still more preferably 1.8×10¹⁹ cm⁻³ or higher, and even more preferably 1.0×10²⁰ cm⁻³. The upper limit of the carrier concentration is not particularly limited, but is preferably 1.0×10²¹ cm⁻³ or lower, and more preferably 5.0×10²⁰ cm⁻³ or lower. From the viewpoint of achieving a high level of both improvement in operating speed and reduction in power loss, the carrier concentration is preferably greater than 3×10¹⁹ cm⁻³.

As described above, in the GaN substrate 1, the resistivity and the thermal conductivity are determined depending on the Ge concentration. For example, as the Ge concentration increases, the carrier concentration increases, the resistivity decreases, and the thermal conductivity decreases. Therefore, in the GaN substrate 1, the Ge concentration may be appropriately changed depending on the required carrier concentration, resistivity, and thermal conductivity.

For example, in the GaN substrate 1, from the viewpoint of setting the resistivity at 25° C. to less than 1×10⁻³ Ω·cm and also setting the thermal conductivity R1(L) in the thickness direction at 25° C. to 140 W/mk or higher, it is preferable that the impurity concentration (for example, Ge concentration) is 7.0×10¹⁹ cm⁻³ or higher, and more preferably 7.0×10¹⁹ cm⁻³ or higher and 1.0×10²¹ cm⁻³ or lower.

Further, for example, in the GaN substrate 1, from the viewpoint of setting the carrier concentration to greater than 3×10¹⁹ cm⁻³ and also setting the thermal conductivity R1(L) in the thickness direction at 25° C. to 140 W/mk or higher, it is preferable that the impurity concentration (for example, Ge concentration) is 3.0×10¹⁹ cm⁻³ or higher, and more preferably 3.0×10¹⁹ cm⁻³ or higher and 1.0×10²¹ cm⁻³ or lower.

### (2) Method of Manufacturing Gallium Nitride Single Crystal Substrate

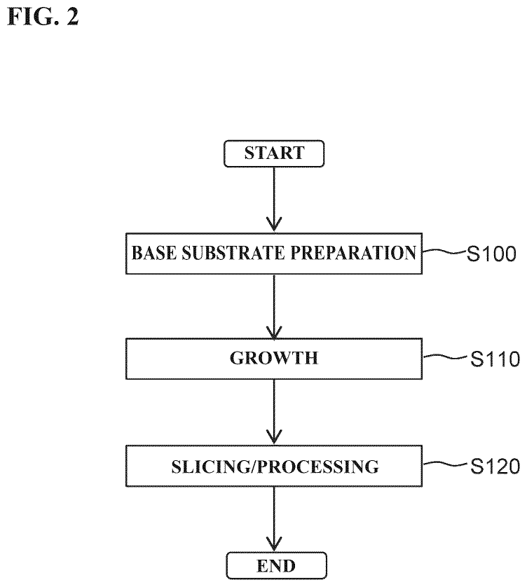

Next, a method of manufacturing the gallium nitride single crystal substrate described above will be explained with reference to FIGS. 1A to 1C and FIG. 2. FIGS. 1A to 1C illustrate schematic cross-sectional views illustrating part of a method of manufacturing a gallium nitride single crystal substrate according to an embodiment of the present disclosure. FIG. 2 illustrates a flowchart indicating the method of manufacturing a gallium nitride single crystal substrate according to this embodiment. As illustrated in FIG. 2, the method of manufacturing a gallium nitride single crystal substrate according to this embodiment includes, for example, a base substrate preparation step S100, a growth step S110, and a slicing/processing step S120.

### (S100: Base Substrate Preparation Step)

First, in the base substrate preparation step S100, as illustrated in FIG. 1A, a base substrate 10 constituted from a gallium nitride single crystal in which a low-index crystal plane closest to a principal surface 10s is a (0001) plane (c-plane) is prepared. Specifically, a commercially available gallium nitride single crystal substrate (not a template, but a free-standing substrate) may be used as the base substrate 10, or a base substrate 10 constituted from a gallium nitride single crystal may be prepared by a conventionally known void-assisted separation (VAS) method. The base substrate 10 may contain, for example, an n-type dopant such as Ge or Si, or may be non-doped. Preferably, the base substrate 10 is constituted by adding the same dopant according to the type of dopant to be added to a growth layer 11 described later. In this way, a concentration difference of dopant between the base substrate 10 and the growth layer 11 can be reduced.

### (S110: Growth Step)

Next, in the growth step S110, as illustrated in FIG. 1B, a GaN single crystal is epitaxially grown on the principal surface 10s of the base substrate 10 prepared in the base substrate preparation step S100, for example, with a c-plane as a growth surface. Specifically, for example, by supplying a source gas to the heated base substrate 10 by an HVPE method, epitaxial growth is directly performed on the principal surface 10s of the base substrate 10, and a growth layer 11 is grown.

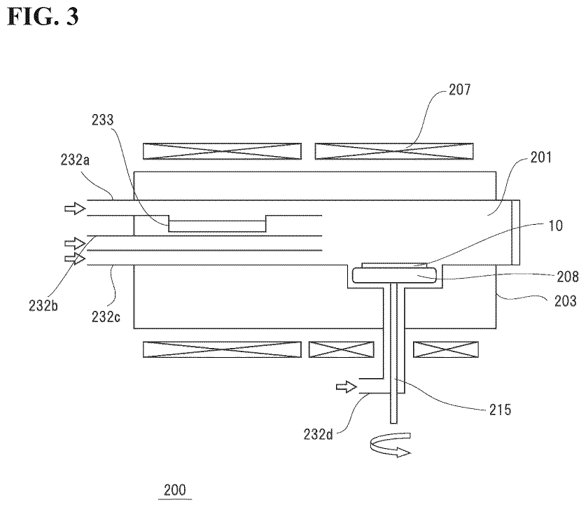

Here, the HVPE apparatus used in this embodiment will be described specifically with reference to FIG. 3.

FIG. 3 illustrates a schematic configuration diagram exemplifying the HVPE apparatus.

An HVPE apparatus 200 is constituted from a heat-resistant material such as quartz, and includes a hermetic container 203 in which a film formation chamber 201 is formed inside. In the film formation chamber 201, a support member 208 (hereinafter also referred to as a holder 208) for holding the base substrate 10 is provided. Around the outer periphery of the hermetic container 203, a heater 207 is provided for heating the base substrate 10 held on the holder 208 and the inside of the gas generator 233 to a desired temperature. The holder 208 is connected to a rotary shaft 215 having a rotation mechanism (not illustrated) and is configured to be rotatable. At one end of the hermetic container 203, gas supply pipes 232a to 232c are connected. These gas supply pipes 232a to 232c are each formed from a heat-resistant material such as quartz and are arranged to supply a predetermined gas to the base substrate 10 in the film formation chamber 201. At the other end of the hermetic container 203, an exhaust pipe (not illustrated) for exhausting the film formation chamber 201 is provided. In this embodiment, a gas supply pipe 232d is arranged to supply gas around the holder 208.

A chlorine-containing gas including a chlorine-based gas (for example, HCl or Cl₂) and a carrier gas is supplied to the gas supply pipe 232a. Downstream of the gas supply pipe 232a, a gas generator 233 for accommodating Ga melt as a source material is provided. In the gas generator 233, gallium chloride (GaCl) gas is generated by a reaction of the chlorine-containing gas with the Ga melt. The generated gallium chloride gas is supplied onto the base substrate 10. The gas supply pipe 232a for supplying GaCl gas as a Ga source gas preferably has its supply port positioned farther from the holder 208 than supply pipes 232b and 232c for supplying other source gases. According to such a configuration, unintended reactions between the GaCl gas discharged from the supply port and ammonia gas supplied by holder purge can be suppressed. As a result, desorption of nitrogen atoms by the holder purge can be suppressed more reliably.

The gas supply pipe 232b is supplied with a carrier gas together with a doping material-containing gas including a doping source gas. As the doping source gas, for example, a tetrachlorogermane (GeCl₄) gas serving as a germanium source can be used at least. The doping source gas will be supplied onto the base substrate 10.

A carrier gas together with an NH₃-containing gas including ammonia gas (NH₃ gas) is supplied to the gas supply pipe 232c. This NH₃-containing gas will be supplied onto the base substrate 10 from the gas supply pipe 232c.

In this embodiment, the gas supply pipe 232d is arranged so as to supply a predetermined gas around the holder 208. In this embodiment, from the viewpoint of suppressing desorption of nitrogen atoms during the process of forming the growth layer 11, ammonia gas is supplied. The ammonia gas is supplied from the gas supply pipe 232d toward the back side of the holder 208 and is flowed from the back side of the holder 208 toward the surface side where the base substrate 10 is held. Therefore, ammonia gas can be continuously supplied to the periphery (outer edge) of the base substrate 10 and the growth interface of the growth layer 11 during crystal growth of the growth layer 11. Thereby, the periphery of the holder 208 can be locally brought into a positive pressure state with ammonia gas. As a result, the growth environment of the GaN crystal can be made N-rich, and even if nitrogen atoms are desorbed, they can be replenished.

Each component of the HVPE apparatus 200 is connected to a controller (not illustrated) configured as a computer, and is configured so that processing procedures and processing conditions described later are controlled by a program executed on the controller.

Specifically, in the growth step S110, in the HVPE apparatus 200, the base substrate 10 to be processed is held on the holder 208. While heating and exhausting of the inside of the film formation chamber 201 are performed, NH₃ gas is supplied into the film formation chamber 201. For example, NH₃ gas is supplied into the film formation chamber 201 from gas supply pipe 232c or gas supply pipe 232d. When the film formation chamber 201 reaches a desired deposition temperature and deposition pressure, and the atmosphere in the film formation chamber 201 becomes an ammonia-containing atmosphere, gases are supplied from gas supply pipes 232a to 232c to supply GaCl gas, a doping material-containing gas (GeCl₄), and NH₃ gas as source gases to the base substrate 10. Here, the doping material-containing gas is preferably supplied so as to epitaxially grow a GaN crystal having a Ge concentration of 5.0×10¹⁸ cm⁻³ or higher. By reacting these gases, it is possible to form a growth layer 11 containing Ge at a high concentration on the base substrate 10. The ammonia-containing atmosphere may contain gases other than ammonia, and may contain, for example, hydrogen.

In this embodiment, from the viewpoint of suppressing desorption of nitrogen atoms from the GaN crystal and occurrence of point defects caused thereby, the crystal growth of the growth layer 11 is performed in such a condition that the inside of the film formation chamber 201 is an ammonia-containing atmosphere and in a pressurizing condition. Here, establishing a pressurizing condition for the growth pressure to as a growth condition in the growth step S110 means performing crystal growth at a pressure higher than atmospheric pressure. Specifically, the growth pressure is set to greater than 1 atm and 1.5 atm or lower. With such growth conditions, desorption of nitrogen atoms during crystal growth can be suppressed. Moreover, ammonia gas is supplied around the base substrate 10, and ammonia is always supplied to the periphery of the growth interface during the process of crystal growth. Thereby, desorption of nitrogen atoms can be suppressed more reliably.

Further, although oxygen (O) may generally be incorporated into the GaN crystal during its growth process, in this embodiment, such incorporation can be suppressed. Specifically, O tends to enter a nitrogen site as an n-type dopant, which may deteriorate the thermal conductivity under a room temperature environment or the decrease of thermal conductivity with temperature increase. In this embodiment, by performing crystal growth of GaN in a pressurizing condition with an ammonia-containing atmosphere while carrying out a holder purge with ammonia gas, the nitrogen partial pressure of the growth interface can be increased, and it is presumed that the entry of O into nitrogen sites can be suppressed as a result. Consequently, the O concentration in the GaN crystal can be reduced, and the O concentration can be made so low as to be negligible relative to the impurity concentration.

Among the growth conditions, other conditions besides the growth pressure are, for example, as follows.

As the growth temperature, the growth temperature is preferably 980° C. or higher and 1200° C. or lower.

The ratio of the supply rate of NH₃ gas as a group-V source gas to the supply rate of GaCl gas as a group-III source gas (hereinafter also referred to as a “V/III ratio”) is preferably 0.1 or more and 5.0 or less.

The partial pressure of GaCl gas is preferably 330 Pa or higher and 1300 Pa or lower.

The partial pressure of the doping material-containing gas is preferably set to, for example, 0.05 Pa or more and 2 Pa or less.

### (S120: Slicing/Processing Step)

In a slicing/processing step S120, as illustrated in FIG. 1C, the growth layer 11 is sliced by a wire saw or the like along a cutting plane approximately parallel to the principal surface 11s (c-plane) of the growth layer 11, for example. Thus, at least one GaN substrate 1 having a diameter of 50 mm or more can be obtained as an as-sliced substrate. At this time, it is preferable to slice it so that the thickness of the GaN substrate 1 becomes, for example, 300 μm or more and 800 μm or less.

After obtaining the GaN substrate 1 as an as-sliced substrate, both surfaces of the GaN substrate 1 may be polished, for example, by a polishing apparatus.

In this embodiment, the GaN substrate 1 obtained in the slicing/processing step S120 may be used as a new base substrate 10, and the growth step S110 and the slicing/processing step S120 may be repeated a plurality of times (for example, four times or more).

By the above steps, the GaN substrate 1 according to this embodiment is manufactured.

The obtained GaN substrate 1 may, for example, be used to fabricate a semiconductor stack by epitaxially growing a semiconductor functional layer constituted from a group-III nitride semiconductor onto its principal surface is. After fabricating the semiconductor stack, electrodes and the like are further formed on the semiconductor stack, and the semiconductor stack is diced to cut out chips of a predetermined size. Thus, a semiconductor device may be fabricated. Since the GaN substrate 1 has high thermal conductivity and excellent heat dissipation, the device performance of the semiconductor device can be maintained at a high level for a long period of time.

### (4) Effects Obtained by this Embodiment

According to this embodiment, one or more of the following effects can be obtained.

(a) The GaN substrate 1 of this embodiment is configured such that the resistivity at 200° C. is 1×10⁻² Ω·cm or lower. In a GaN substrate 1, it is needed to add an impurity in order to reduce the resistivity, and by adding the impurity, nitrogen vacancies or the like may be formed in the crystal growth process, so that point defects may occur. In this respect, in this embodiment, the crystal growth of the GaN substrate 1 is carried out under a pressurizing condition in an ammonia-containing atmosphere. This makes it feasible to suppress desorption of nitrogen atoms in the GaN substrate 1. Moreover, the crystal growth is carried out while performing holder purge by locally supplying ammonia gas around the base substrate 10. As a result, ammonia gas can be continuously supplied around the growth interface of the GaN crystal, and desorption of nitrogen atoms can be more effectively suppressed. Consequently, in the process of crystal growth of the GaN crystal, despite the impurity concentration being high, desorption of nitrogen atoms can be suppressed and generation of point defects can be reduced. According to the GaN substrate 1 thus obtained, while lowering the resistivity, the thermal conductivity in the thickness direction can be maintained high even under a high-temperature environment. Specifically, in the GaN substrate 1, the thermal conductivity R1(H) in the thickness direction at 200° C. can be 80 W/mk to 120 W/mk. With such a GaN substrate 1, because of its low resistivity, when fabricating, for example, a high-power laser diode or a power device, switching characteristics can be improved and ON resistance can be reduced even under a high-temperature environment. Moreover, even under a high-temperature environment, high heat dissipation can be realized and high device performance can be maintained.

As a comparative embodiment, when the pressure is reduced in an ammonia-containing atmosphere or holder purge is performed with hydrogen or nitrogen, deterioration of crystallinity due to high-concentration doping of impurities cannot be sufficiently suppressed, and point defects tend to increase. In a GaN substrate obtained under such conditions, even if high thermal conductivity is exhibited under a room temperature environment, the thermal conductivity tends to decrease under a high-temperature environment, and the thermal conductivity R1(H) in the thickness direction and the thermal conductivity R2(H) in the in-plane direction tend to decrease. In this respect, according to the growth conditions of this embodiment, reduction of thermal conductivity with increasing temperature is suppressed, and high thermal conductivity can be maintained even under a high-temperature environment.

(b) It is preferable that in the GaN substrate 1, the thermal conductivity R1(L) in the thickness direction at 25° C. is 120 W/mk or higher and 230 W/mk or lower. Thus, under a room (ambient) temperature environment, the thermal conductivity in the thickness direction can be increased, and for example, when fabricating a semiconductor device therefrom, discharge of heat to a heat sink can be promoted.

(c) It is preferable that, in the GaN substrate 1, when the thermal conductivity in the thickness direction is defined as R1, the rate of change x of R1 when the temperature is raised from 25° C. to 200° C. is 0.5 or lower. According to such a GaN substrate 1, reduction of thermal conductivity due to temperature rise is suppressed, and the thermal conductivity R1(H) in the thickness direction can be maintained high even under a high-temperature environment. Therefore, in a semiconductor device fabricated from the GaN substrate 1, even when the temperature rises, discharge of heat to a heat sink can be maintained.

(d) Since point defects are suppressed in the GaN substrate 1, the thermal conductivity R2 along the in-plane direction can be maintained high together with the thermal conductivity R1 in the thickness direction. Specifically, it is preferable that the thermal conductivity R2(L) along the in-plane direction at 25° C. is 150 W/mk or higher, and the thermal conductivity R2(H) in the in-plane direction at 200° C. is 80 W/mk to 110 W/mk. According to such a GaN substrate 1, when fabricating a semiconductor device therefrom, heat generated inside the device can be diffused and localized overheating can be suppressed, thereby maintaining high device characteristics.

(e) It is preferable that, in the GaN substrate 1, when the thermal conductivity in the in-plane direction is defined as R2, the rate of change y of R2 when the temperature is raised from 25° C. to 200° C. is 0.6 or lower. According to such a GaN substrate 1, reduction of thermal conductivity due to temperature rise is suppressed, and the thermal conductivity R2 in the in-plane direction can be maintained high even under a high-temperature environment. Therefore, in a semiconductor device fabricated from the GaN substrate 1, heat generated inside the device can be diffused in the in-plane direction, and localized overheating can be more reliably suppressed.

(f) It is preferable that the GaN substrate 1 includes an impurity containing Ge and that the Ge concentration is 1.0×10¹⁸ cm⁻³ or higher. According to such a Ge concentration, the resistivity of the GaN substrate 1 at 200° C. can be further reduced. On the other hand, it is preferable that the Ge concentration is 1.0×10²¹ cm⁻³ or lower. According to such a Ge concentration, while lowering the resistivity of the GaN substrate 1, the thermal conductivity R1(H) in the thickness direction at 200° C. can be maintained high.

(g) It is preferable that the GaN substrate 1 contains oxygen in addition to Ge as an impurity, and that the O concentration is 1/10 or lower of the Ge concentration. In this way, the above effect (a) can be more reliably obtained.

(h) It is preferable that the O concentration in the GaN substrate 1 is 6×10¹⁶ cm⁻³ or lower. In this way, the above effect (g) can be more reliably obtained.

(i) It is preferable that the carrier concentration of the GaN substrate 1 is 1.0×10¹⁸ cm⁻³ or higher. According to such a GaN substrate 1, the operating speed of a semiconductor device can be improved, and power loss can be reduced.

(j) In this embodiment, the growth pressure in the growth atmosphere only needs to be under a pressurizing condition, and preferably, it is greater than 1 atm and 1.5 atm or lower. By setting such a growth pressure, desorption of nitrogen atoms in the crystal growth process of the GaN crystal can be more reliably suppressed.

(k) Moreover, in the crystal growth process of the GaN crystal, it is preferable that the supply port of the Ga raw material gas supply pipe 232a is disposed at a position farthest from the base substrate 10. As a result, the reaction between the Ga raw material gas and the ammonia gas supplied for holder purge can be suppressed, and desorption of nitrogen atoms can be more reliably suppressed.

### Other Embodiments

Embodiments of the present disclosure have been described specifically above. However, the present disclosure is not limited to the above embodiments, and various modifications can be made without departing from the gist thereof.

In the above embodiments, a case has been described in which a GaN crystal is grown on a base substrate constituted from a GaN crystal. However, the present disclosure is not limited thereto. In the present disclosure, it is not limited to homoepitaxial growth, and heteroepitaxial growth may be performed. In this case, a conventionally known VAS method may be adopted, and after forming a growth layer by growing a GaN crystal on a base substrate, the growth layer may be removed.

In the above embodiments, the case has been described in which the growth layer 11 is sliced in the slicing/processing step S120 using a wire saw. However, for example, an outer blade slicer, an inner blade slicer, an electric discharge machine, or the like may be used.

### Examples

Next, examples according to the present disclosure will be described. These examples are merely examples of the present disclosure, and the present disclosure is not limited by these examples.

### (1) Fabrication of Gallium Nitride Single Crystal Substrate

Gallium nitride single crystal substrates of Samples 1 to 3 were fabricated as follows.

### [Fabrication Conditions of Sample 1](Base Substrate)

Material: GaN
Fabrication method: VAS method
Diameter: 2 inches Thickness: 400 μm
Low-index crystal plane closest to principal surface: c-plane
Root mean square roughness RMS of principal surface: 0.5 nm

### (Growth Layer)

Material: GaN
Growth method: HVPE method
Growth temperature: 980° C. or higher and 1200° C. or lower
Growth pressure: 1.2 atm or higher and 1.5 atm or lower
Growth atmosphere: ammonia, hydrogen
V/III ratio: 0.1 or more and 5.0 or less
Ge doping method: GeCl₄ gas
Partial pressure of GeCl₄ gas: 0.15 Pa
Thickness of growth layer: 2000 μm (holder purge conditions)
Gas: ammonia gas
Supply amount: 1.0 L/min

### (Slicing/Processing Conditions)

Thickness of gallium nitride single crystal substrate: 400 μm
Kerf loss: 200 μm

A GaN substrate was fabricated under the above fabrication conditions. When the Ge concentration of the GaN substrate was measured by secondary ion mass spectrometry, the Ge concentration was 7.05×10¹⁸ cm⁻³. When the O concentration was measured similarly, the O concentration was 1.00×10¹⁶ cm⁻³ to 6.00×10¹⁶ cm⁻³. That is, the O concentration was 1/100 or less of the Ge concentration.

### [Fabrication Conditions of Sample 2]

In Sample 2, a GaN substrate was fabricated under similar conditions to Sample 1, except that the partial pressure of GeCl₄ gas was set to 0.39 Pa so that the Ge concentration was higher than that of Sample 1. When the Ge concentration of the GaN substrate was measured by secondary ion mass spectrometry, the Ge concentration was 1.99×10¹⁹ cm⁻³. When the O concentration was measured similarly, the O concentration was 1.00×10¹⁶ cm⁻³ to 6.00×10¹⁶ cm⁻³. That is, the O concentration was 1/100 or less of the Ge concentration.

### [Fabrication Conditions of Sample 3]

In Sample 3, a GaN substrate was fabricated under similar conditions to Sample 1, except that the partial pressure of GeCl₄ gas was set to 1.85 Pa so that the Ge concentration was higher than that of Sample 2. When the Ge concentration of the GaN substrate was measured by secondary ion mass spectrometry, the Ge concentration was 1.03×10²⁰ cm⁻³. When the O concentration was measured similarly, the O concentration was 1.00×10¹⁶ cm⁻³ to 6.00×10¹⁶ cm⁻³. That is, the O concentration was 1/100 or less of the Ge concentration.

### [Fabrication Conditions of Sample 4]

In Sample 4, although the growth of the GaN crystal was carried out in an ammonia-containing atmosphere, the growth pressure was set to a low pressure of 0.6 atm. The partial pressure of GeCl₄ gas was set to 0.39 Pa and the Ge concentration was adjusted to be comparable to that of Sample 2. Furthermore, during the growth of the GaN crystal, nitrogen gas was supplied to the outer edge of the base substrate instead of ammonia gas to perform holder purge. Except for the above, the GaN substrate was fabricated under similar conditions to Sample 1. The Ge concentration of the GaN substrate was measured by secondary ion mass spectrometry, and the Ge concentration was 2.08×10¹⁹ cm⁻³. Similarly, when the O concentration was measured, the O concentration was higher compared with Samples 1 to 4, and was 6.00×10¹⁶ cm⁻³ to 1.00×10¹⁷ cm⁻³.

### (2) Evaluation

The fabricated GaN substrates were evaluated in terms of resistivity, carrier concentration, and thermal conductivity along the thickness direction and the in-plane direction under respective temperature conditions of 25° C. and 200° C. The measurement methods are described below.

### (Resistivity)

The resistivity of the GaN substrate was measured at 25° C. and 200° C., respectively. Specifically, the resistivity at 25° C. was determined by performing a Hall effect measurement using the Van der Pauw method on a sample taken from the GaN substrate. The resistivity at 200° C. was determined by heating the sample having been taken to 200° C. and then performing a similar operation to the measurement of the resistivity at 25° C.

### (Carrier Concentration)

The carrier concentration was determined by performing a Hall effect measurement on the sample taken from the GaN substrate.

### Thermal Conductivity in Thickness Direction

The thermal conductivity R1(L) [W/m·K] in the thickness direction at 25° C. was calculated from R1(L)=αρCp by determining density ρ [kg/m³], specific heat Cp [J/kg·K], and thermal diffusivity α [m²/s] of a sample taken from the GaN substrate. Density was determined by the Archimedes method. Specific heat was determined by specific heat capacity measurement using a DSC method. Thermal diffusivity was determined by thermal diffusivity measurement using a flash method. The thermal diffusivity was measured using a measurement device “LFA467HT” manufactured by NETZSCH.

The thermal conductivity R1(H) [W/m·K] in the thickness direction at 200° C. was calculated by determining density, specific heat, and thermal diffusivity of a sample taken from the GaN substrate in a similar manner to that described above, with the sample temperature changed from 25° C. to 200° C. The density at 25° C. was adopted, since thermal expansion due to temperature increase is negligible.

Thermal Conductivity in in-Plane Direction

The thermal conductivity R2(L) [W/m·K] in the in-plane direction at 25° C. was calculated from R2(L)=αρCp by determining density ρ [kg/m³], specific heat Cp [J/kg·K], and thermal diffusivity α [m²/s] of a sample taken from the GaN substrate. Thermal diffusivity was determined by thermal diffusivity measurement using an optical AC method. As the thermal diffusivity measurement device, “Laser PIT” manufactured by ULVAC-RIKO, Inc. was used. The density and specific heat were measured in a similar manner to the above.

The thermal conductivity R2(H) [W/m·K] in the in-plane direction at 200° C. was calculated by determining density, specific heat, and thermal diffusivity of a sample taken from the GaN substrate in a similar manner to that described above, with the sample temperature changed from 25° C. to 200° C. The density at 25° C. was adopted, since thermal expansion due to temperature increase is negligible.

### (3) Evaluation Results the Evaluation Results are Summarized in Table 1 Below.

TABLE 1

| | | Sample 1 | Sample 2 | Sample 3 | Sample 4 |
|---|---|---|---|---|---|
| Ge concentration (cm⁻³) | | 7.05E+18 | 1.99E+19 | 1.03E+20 | 2.08E+19 |
| Carrier concentration (cm⁻³) | | 7.06E+18 | 2.00E+19 | 1.03E+20 | 2.09E+19 |
| Resistivity (25° C.) [Ω cm] | | 6.90E−03 | 2.60E−03 | 7.50E−04 | 7.80E−04 |
| Thermal conductivity R1 | R1(L) at | 186 | 156 | 141 | 151 |
| (thickness direction) | 25° C. | | | | |
| [W/m · K] | R1(H) | 107 | 103 | 91.6 | 74 |
| | at 200° C. | | | | |
| Rate of change x of thermal | | 0.42 | 0.34 | 0.35 | 0.51 |
| conductivity R1 | | | | | |
| Thermal conductivity R2 | R2(L) at | 237 | 202 | 173 | 198 |
| (in-plane direction) | 25° C. | | | | |
| [W/m · K] | R2(H) | 96.5 | 95.6 | 89.1 | 78 |
| | at 200° C. | | | | |

| | | | | |
|---|---|---|---|---|
| Rate of change y of thermal | 0.59 | 0.53 | 0.48 | 0.61 |
| conductivity R2 | | | | |

As can been seen from Table 1, in Samples 1 to 3, since the Ge concentration is 1.0×10¹⁸ cm⁻³ or higher, it was confirmed that the resistivity at 25° C. is 1λ10⁻² Ω·cm or lower. Further, the resistivity at 200° C. was also as low as that at 25° C., and it was confirmed that it is 1×10⁻² Ω·cm or lower. That is, in Samples 1 to 3, it was confirmed that the resistivity becomes low in both room temperature and high-temperature environments.

On the other hand, in the GaN substrate 1, it was confirmed that the thermal conductivity R1(H) in the thickness direction at 200° C. can be made as high as 80 W/mk to 120 W/mk. It was also confirmed that the thermal conductivity R2(H) in the in-plane direction at 200° C. is as high as 80 W/mk to 110 W/mk.

Further, in Samples 1 to 3, it was confirmed that both the thermal conductivity R1(L) in the thickness direction at 25° C. and the thermal conductivity R2(L) in the in-plane direction at 25° C. are high. Specifically, the thermal conductivity R1(L) at 25° C. was 120 W/mk or higher, and the thermal conductivity R2(L) at 25° C. was 150 W/mk or higher.

Thus, in Samples 1 to 3, it was confirmed that although Ge was doped at a high concentration, reduction in thermal conductivity due to addition of Ge is suppressed, and the thermal conductivity can be maintained high not only under a room temperature environment but also under a high-temperature environment.

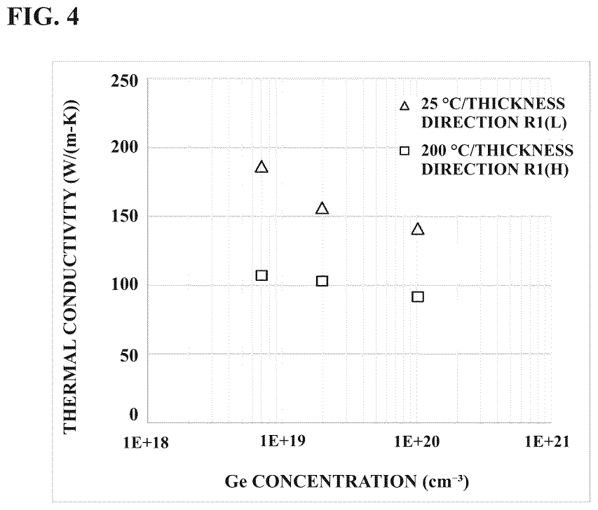

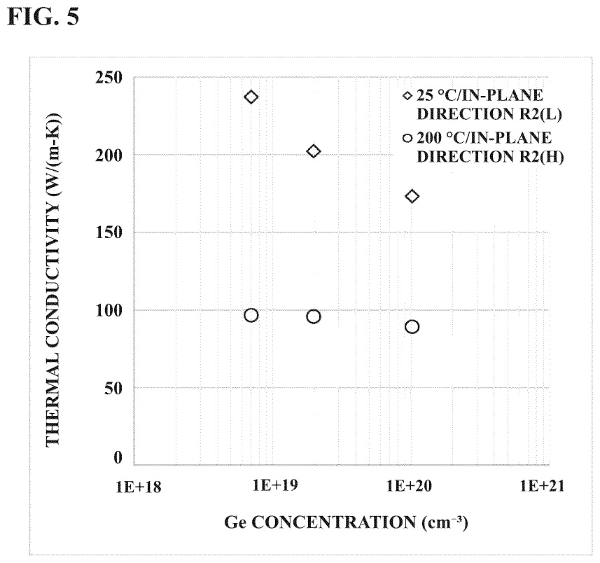

Hereinafter, the thermal conductivity will be specifically described with reference to FIGS. 4 and 5. FIG. 4 illustrates a variation in the thermal conductivity R1(L) and R1(H) in the thickness direction at 25° C. and 200° C. with respect to the Ge concentration. FIG. 5 illustrates a variation in the thermal conductivity R2(L) and R2(H) in the in-plane direction at 25° C. and 200° C. with respect to the Ge concentration. In each figure, the horizontal axis indicates the Ge concentration and the vertical axis indicates the thermal conductivity.

As illustrated in FIG. 4, it was confirmed that as the Ge concentration increases, the thermal conductivity R1 in the thickness direction tends to decrease. As illustrated in FIG. 5, it was confirmed that as the Ge concentration increases, the thermal conductivity R2 in the in-plane direction tends to decrease. It was also confirmed that the thermal conductivity in each direction tends to decrease as the temperature rises from 25° C. to 200° C.

However, in Samples 1 to 3, it was confirmed that the decrease in thermal conductivity due to temperature rise is small. Specifically, as can be seen in Table 1, when the temperature was raised from 25° C. to 200° C., the rate of change x of the thermal conductivity R1 in the thickness direction was 0.5 or lower, and the rate of change y of the thermal conductivity R2 in the in-plane direction was 0.6 or lower.

The reason why in Samples 1 to 3 the thermal conductivity could be maintained high not only in a room temperature environment but also in a high-temperature environment is presumed to be because the growth conditions were such that the occurrence of point defects was suppressed.

In contrast, in Sample 4, although the resistivity at 25° C. and 200° C. was as low as that of Sample 1 and the thermal conductivities R1(L) and R2(L) at 25° C. were as high as those of Sample 1, it was confirmed that the thermal conductivities R1(H) and R2(H) at 200° C. are significantly lower. It was also confirmed that the rates of change x and y of thermal conductivity due to temperature rise were both high, and the decrease in thermal conductivity due to temperature rise was large. This is presumed to be caused by an increase in point defects due to nitrogen loss in the GaN crystal.

Accordingly, it was confirmed that by performing crystal growth of the growth layer under a pressurizing condition in an ammonia-containing atmosphere while performing holder purge with ammonia gas, it is possible to fabricate a GaN substrate capable of maintaining high thermal conductivity even under a high-temperature environment while reducing the resistivity. According to such a GaN substrate, since high heat dissipation can be exhibited even under a high-temperature environment, the performance of a semiconductor device can be maintained high over a long period of time.

### <Preferred Embodiment of the Present Disclosure> Hereinafter, a Preferred Embodiment of the Present Disclosure Will be Supplementary Description

### (Supplementary Description 1)

A gallium nitride single crystal substrate in which a low-index crystal plane closest to a principal surface of the substrate is a (0001) plane, wherein
resistivity of the substrate at 200° C. is 1×10⁻² Ω·cm or lower, and
thermal conductivity of the substrate along a thickness direction at 200° C. is 80 W/mk or higher.

### (Supplementary Description 2)

The gallium nitride single crystal substrate according to Supplementary description 1, wherein thermal conductivity of the substrate along a thickness direction at 25° C. is 120 W/mk or higher and 230 W/mk or lower.

### (Supplementary Description 3)

The gallium nitride single crystal substrate according to Supplementary description 2, wherein provided that the thermal conductivity of the substrate along a thickness direction at 200° C. is R(H), and the thermal conductivity of the substrate along a thickness direction at 25° C. is R(L), R(H) and R(L) satisfy (R(L)−R(H))/R(L)<0.5.

### (Supplementary Description 4)

The gallium nitride single crystal substrate according to any one of Supplementary descriptions 1 to 3, wherein
the substrate includes an impurity containing germanium, and
a germanium concentration is 1.0×10¹⁸ cm⁻³ or higher.

### (Supplementary Description 5)

The gallium nitride single crystal substrate according to Supplementary description 4, wherein
the impurity contains oxygen, and
an oxygen concentration is 1/10 or lower of the germanium concentration.

### (Supplementary Description 6)

A gallium nitride single crystal substrate in which a low-index crystal plane closest to a principal surface of the substrate is a (0001) plane, wherein
resistivity of the substrate at 25° C. is less than 1×10⁻³ Ω·cm, and
thermal conductivity of the substrate along a thickness direction at 25° C. is 140 W/mk or higher.

### (Supplementary Description 7)

The gallium nitride single crystal substrate according to Supplementary description 6, wherein
the substrate includes an impurity containing germanium, and
a germanium concentration is 7.0×10¹⁹ cm⁻³ or higher.

### (Supplementary Description 8)

A gallium nitride single crystal substrate in which a low-index crystal plane closest to a principal surface of the substrate is a (0001) plane, wherein
carrier concentration is greater than 3×10¹⁹ cm⁻³, and
thermal conductivity of the substrate along a thickness direction at 25° C. is 140 W/mk or higher.

### (Supplementary Description 9)

A method of producing a gallium nitride single crystal substrate, the method comprising:
(a) preparing a base substrate constituted from a gallium nitride single crystal in which a low-index crystal plane closest to a principal surface of the base substrate is a (0001) plane; and
(b) epitaxially growing a gallium nitride single crystal on the principal surface of the base substrate,
wherein in (b), under an ammonia-containing atmosphere with a growth pressure greater than 1 atm and 1.5 atm or lower, a source gas for forming the gallium nitride single crystal is supplied onto the base substrate, and concurrently ammonia is supplied from around a support member supporting the base substrate.

### (Supplementary Description 10)

The method of producing a gallium nitride single crystal substrate according to Supplementary description 9, wherein
in (b), among supply ports for supplying source gas, a supply port for supplying a Ga-containing gas is disposed at a position farther from the base substrate than supply ports for supplying other source gases.

### EXPLANATION OF REFERENCE SYMBOLS

1: Gallium nitride single crystal substrate (GaN substrate)
10: Base substrate
11: Growth layer.

What is claimed is:

1. A gallium nitride single crystal substrate in which a low-index crystal plane closest to a principal surface of the substrate is a (0001) plane,
wherein resistivity of the substrate at 200° C. is 1×10⁻² Ω·cm or lower, and
thermal conductivity of the substrate along a thickness direction at 200° C. is 80 W/mk or higher.

2. The gallium nitride single crystal substrate according to claim 1,
wherein thermal conductivity of the substrate along a thickness direction at 25° C. is 120 W/mk or higher and 230 W/mk or lower.

3. The gallium nitride single crystal substrate according to claim 2,
wherein provided that the thermal conductivity of the substrate along a thickness direction at 200° C. is R(H), and the thermal conductivity of the substrate along a thickness direction at 25° C. is R(L),
R(H) and R(L) satisfy (R(L)−R(H))/R(L)<0.5.

4. The gallium nitride single crystal substrate according to claim 1,
wherein the substrate includes an impurity containing germanium,
and a germanium concentration is 1.0×10¹⁸ cm⁻³ or higher.

5. The gallium nitride single crystal substrate according to claim 4,
wherein the impurity contains oxygen,
and an oxygen concentration is 1/10 or lower of the germanium concentration.

6. A method of producing a gallium nitride single crystal substrate, the method comprising:
(a) preparing a base substrate constituted from a gallium nitride single crystal in which a low-index crystal plane closest to a principal surface of the base substrate is a (0001) plane; and
(b) epitaxially growing a gallium nitride single crystal on the principal surface of the base substrate,
wherein in (b), under an ammonia-containing atmosphere with a growth pressure greater than 1 atm and 1.5 atm or lower, a source gas for forming the gallium nitride single crystal is supplied onto the base substrate, and concurrently ammonia is supplied from around a support member supporting the base substrate.
